(19) United States
(12) Patent Application Publication
(10) Pub. No.: US 2022/0284966 A1
(43) Pub. Date: Sep. 8, 2022

(54) STATIC RANDOM ACCESS MEMORY AND OPERATION METHOD THEREOF

(71) Applicant: Powerchip Semiconductor Manufacturing Corporation, Hsinchu (TW)

(72) Inventor: Yi-Chung Liang, Tainan City (TW)

(73) Assignee: Powerchip Semiconductor Manufacturing Corporation, Hsinchu (TW)

(21) Appl. No.: 17/229,823

(22) Filed: Apr. 13, 2021

(30) Foreign Application Priority Data
Mar. 3, 2021 (TW) 110107514

(51) Int. Cl. G11C 16/14; G11C 16/10; G11C 16/26; G11C 16/24; G11C 16/30; G11C 16/04; H03K 19/017

(52) U.S. Cl. CPC G11C 16/14; G11C 16/102; G11C 16/26; G11C 16/24; G11C 16/30; G11C 16/0425; H03K 19/01742

(57) ABSTRACT

A static random access memory including at least one memory cell is provided. The memory cell includes a first inverter, a second inverter, a first pass gate transistor, a second pass gate transistor, a first non-volatile memory, and a second non-volatile memory. The first inverter and the second inverter are coupled to each other. The first pass gate transistor is coupled between the first inverter and the first bit line. The second pass gate transistor is coupled between the second inverter and the second bit line. The first non-volatile memory is coupled between the first pass gate transistor and the first bit line. The second non-volatile memory is coupled between the second pass gate transistor and the second bit line.

### CROSS-REFERENCE TO RELATED APPLICATION

This application claims the priority benefit of Taiwan application serial no. 110107514, filed on Mar. 3, 2021. The entirety of the above-mentioned patent application is hereby incorporated by reference herein and made a part of this specification.

### BACKGROUND OF THE INVENTION

### Field of the Invention

The invention relates to a memory and an operation method thereof, and particularly relates to a static random access memory (SRAM) and an operation method thereof.

### Description of Related Art

The random access memory can be mainly divided into the dynamic random access memory (DRAM) and the static random access memory (SRAM). The SRAM has the characteristics of fast operation and low power consumption. Compared with the DRAM, the SRAM is simpler in design and manufacturing. Therefore, the SRAM is widely used in electronic products. However, how to further improve the electrical performance of the SRAM is the goal of continuous efforts.

### SUMMARY OF THE INVENTION

The invention provides an SRAM and an operation method thereof, which can effectively improve the electrical performance of the memory device.

The invention provides a SRAM, which includes at least one memory cell. The memory cell includes a first inverter, a second inverter, a first pass gate transistor, a second pass gate transistor, a first non-volatile memory, and a second non-volatile memory. The first inverter and the second inverter are coupled to each other. The first pass gate transistor is coupled between the first inverter and the first bit line. The second pass gate transistor is coupled between the second inverter and the second bit line. The first non-volatile memory is coupled between the first pass gate transistor and the first bit line. The second non-volatile memory is coupled between the second pass gate transistor and the second bit line.

According to an embodiment of the invention, in the SRAM, the first inverter may include a first pull-up transistor and a first pull-down transistor coupled to each other. The second inverter may include a second pull-up transistor and a second pull-down transistor coupled to each other.

According to an embodiment of the invention, in the SRAM, each of the first non-volatile memory and the second non-volatile memory may be a split gate flash memory.

According to an embodiment of the invention, in the SRAM, each of the first non-volatile memory and the second non-volatile memory may include a first gate, a second gate, a third gate, and a charge storage layer. The first gate is located on the substrate. The second gate is located on the substrate on one side of the first gate. The third gate is located on the substrate between the first gate and the second gate. The charge storage layer is located between the third gate and the substrate.

According to an embodiment of the invention, in the SRAM, the first non-volatile memory and the first pass gate transistor may share the second gate.

According to an embodiment of the invention, in the SRAM, the second non-volatile memory and the second pass gate transistor may share the second gate.

According to an embodiment of the invention, in the SRAM, two adjacent memory cells may share the first gate and the third gate.

According to an embodiment of the invention, in the SRAM, the top view shape of the first gate may be an H shape.

According to an embodiment of the invention, in the SRAM, the top view shape of the third gate may be a ring shape.

According to an embodiment of the invention, in the SRAM, the charge storage layer is, for example, a floating gate.

According to an embodiment of the invention, in the SRAM, each of the first non-volatile memory and the second non-volatile memory may further include a first doped region and a second doped region. The first doped region is located in the substrate below the first gate. The second doped region is located in the substrate on one side of the second gate.

According to an embodiment of the invention, in the SRAM, two adjacent memory cells may share the first doped region.

According to an embodiment of the invention, in the SRAM, the first doped region may extend into the substrate on one side of the first gate.

According to an embodiment of the invention, the SRAM may further include a contact. The contact is coupled to the first doped region.

According to an embodiment of the invention, in the SRAM, the first gate, the second gate, the third gate, the charge storage layer, and the substrate may be electrically insulated from each other.

The invention provides an operation method of the SRAM, which includes performing a program operation on the memory cell. The method of the program operation includes the following steps. The first non-volatile memory and the second non-volatile memory are erased. The memory cell is programmed so that the memory cell has a storage state. In the storage state, one of the first inverter and the second inverter outputs a high voltage signal, and the other of the first inverter and the second inverter outputs a low voltage signal. One of the first non-volatile memory and the second non-volatile memory coupled to the low voltage signal is programmed before the power is turned off.

According to an embodiment of the invention, in the operation method of the SRAM, the method of erasing the first non-volatile memory and the second non-volatile memory is, for example, a Fowler-Nordheim (FN) tunneling method.

According to an embodiment of the invention, in the operation method of the SRAM, the method of programming one of the first non-volatile memory and the second non-volatile memory coupled to the low voltage signal is, for example, the FN tunneling method.

According to an embodiment of the invention, the operation method of the SRAM may further include performing a read operation on the memory cell. The method of the read operation may include the following steps. The power is turned on. Operating voltages are applied to the first bit line and the second bit line respectively, and the first pass gate transistor and the second pass gate transistor are turned on, so that the memory cell is restored to the storage state which is before the power is turned off.

According to an embodiment of the invention, the operation method of the SRAM may further include the following step. The program operation is performed on the memory cell again after the read operation is performed on the memory cell.

Based on the above description, in the SRAM and the operation method thereof, after the power is turned on again, the memory cell can be restored to the storage state which is before the power is turned off by the first non-volatile memory and the second non-volatile memory. Therefore, the operation complexity is greatly reduced, and the electrical performance of the memory device is effectively increased.

In order to make the aforementioned and other objects, features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic circuit diagram illustrating a SRAM according to an embodiment of the invention.

FIG. 2 is a top view illustrating a SRAM according to an embodiment of the invention.

FIG. 3 is a cross-sectional view taken along section line I-I′ in FIG. 2.

FIG. 4 is a cross-sectional view taken along section line II-II′ in FIG. 2.

FIG. 5 is a flowchart of operating a SRAM according to an embodiment of the invention.

### DESCRIPTION OF THE EMBODIMENTS

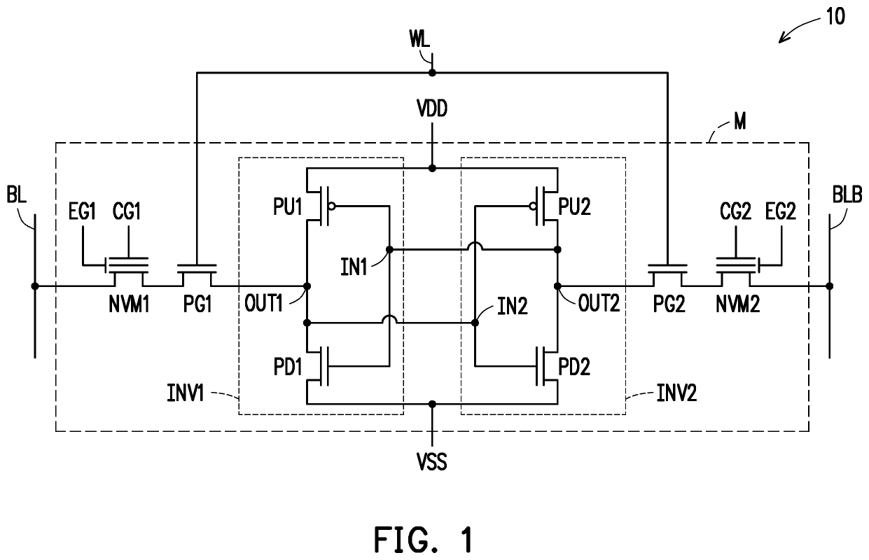

FIG. 1 is a schematic circuit diagram illustrating a SRAM according to an embodiment of the invention.

Referring to FIG. 1, a SRAM 10 includes at least one memory cell M. The memory cell M includes an inverter INV1, an inverter INV2, a pass gate transistor PG1, a pass gate transistor PG2, a non-volatile memory NVM1, and a non-volatile memory NVM2. The inverter INV1 and the inverter INV2 are coupled to each other. That is, the output terminal OUT1 of the inverter INV1 is connected to the input terminal IN2 of the inverter INV2, and the output terminal OUT2 of the inverter INV2 is connected to the input terminal IN1 of the inverter INV1. In some embodiments, the inverter INV1 may include a pull-up transistor PU1 and a pull-down transistor PD1 coupled to each other, and the inverter INV2 may include a pull-up transistor PU2 and a pull-down transistor PD2 coupled to each other.

The pass gate transistor PG1 is coupled between the inverter INV1 and the bit line BL. In some embodiments, the drain of the pass gate transistor PG1 may be coupled to the output terminal OUT1 of the inverter INV1, and the source of the pass gate transistor PG1 may be coupled to the bit line BL. The pass gate transistor PG2 is coupled between the inverter INV2 and the bit line BLB. In some embodiments, the drain of the pass gate transistor PG2 may be coupled to the output terminal OUT2 of the inverter INV2, and the source of the pass gate transistor PG2 may be coupled to the bit line BLB. The gate of the pass gate transistor PG1 and the gate of the pass gate transistor PG2 may be coupled to the word line WL. The pass gate transistor PG1 and the pass gate transistor PG2 may be N-type metal oxide semiconductor transistors (NMOS transistors).

In addition, the source of the pull-up transistor PU1 and the source of the pull-up transistor PU2 may be coupled to the voltage terminal VDD. The source of the pull-down transistor PD1 and the source of the pull-down transistor PD2 may be coupled to the voltage terminal VSS. The pull-up transistor PU1 and the pull-up transistor PU2 may be P-type metal oxide semiconductor transistors (PMOS transistors). The pull-down transistor PD1 and the pull-down transistor PD2 may be NMOS transistors.

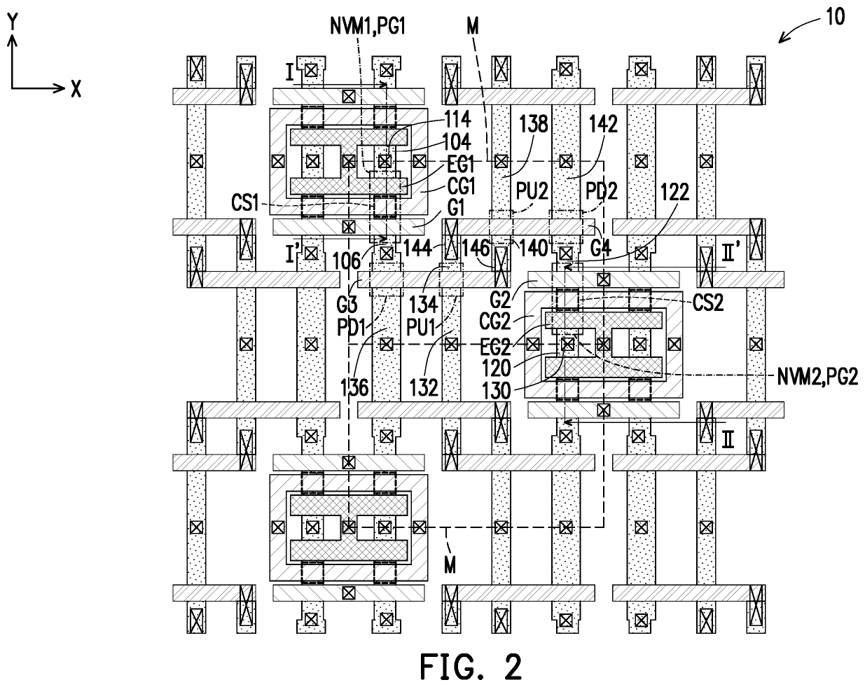

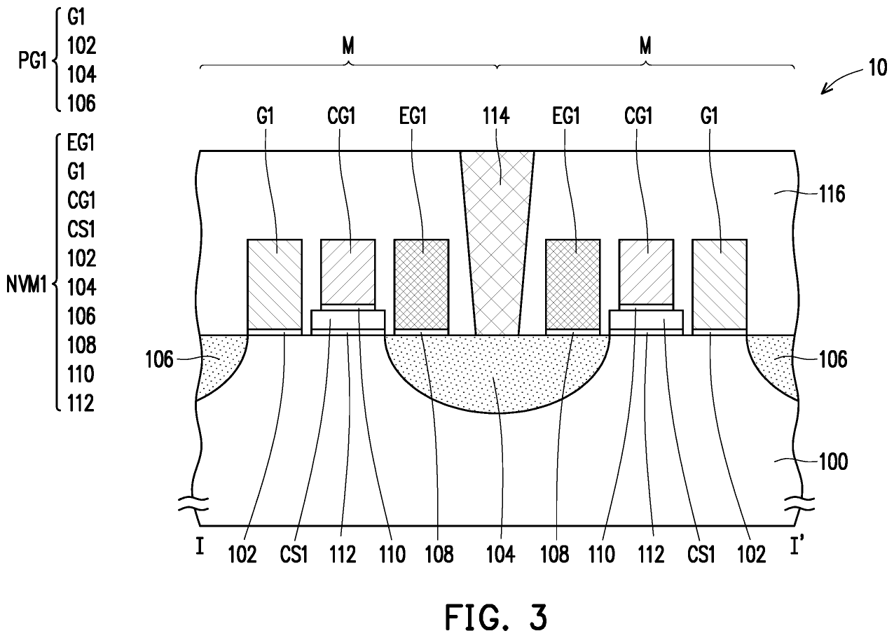

The non-volatile memory NVM1 is coupled between the pass gate transistor PG1 and the bit line BL. The non-volatile memory NVM2 is coupled between the pass gate transistor PG2 and the bit line BLB. In some embodiments, the non-volatile memory NVM1 and the pass gate transistor PG1 may have shared components (e.g., the gate and the doped region), and the non-volatile memory NVM2 and the pass gate transistor PG2 may have shared components (e.g., the gate and the doped region) (referring to the description of FIG. 2 and FIG. 3).

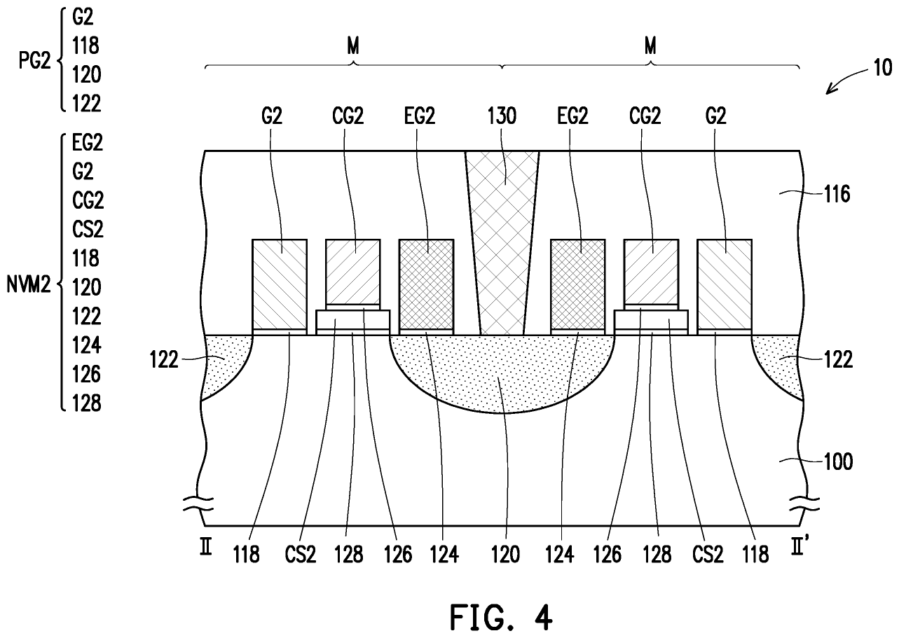

FIG. 2 is a top view illustrating a SRAM according to an embodiment of the invention. FIG. 3 is a cross-sectional view taken along section line I-I′ in FIG. 2. FIG. 4 is a cross-sectional view taken along section line II-II′ in FIG. 2.

Referring to FIG. 1 to FIG. 3, the pass gate transistor PG1 may include a gate G1, a dielectric layer 102, a doped region 104, and a doped region 106. The gate G1 is located on the substrate 100. The material of the gate G1 is, for example, a conductive material such as doped polysilicon. The dielectric layer 102 is located between the gate G1 and the substrate 100. The material of the dielectric layer 102 is, for example, a dielectric material such as silicon oxide. The doped region 104 and the doped region 106 are respectively located in the substrate 100 on one side and the other side of the gate G1. In some embodiments, the doped region 104 may be used as the source of the pass gate transistor PG1, and the doped region 106 may be used as the drain of the pass gate transistor PG1.

The non-volatile memory NVM1 may be a split gate flash memory. In the present embodiment, the non-volatile memory NVM1 is, for example, a third-generation embedded SuperFlash (ESF3) memory, but the invention is not limited thereto. The non-volatile memory NVM1 may include a gate EG1, a gate G1, a gate CG1, and a charge storage layer CS1.

The gate EG1 is located on the substrate 100. The gate EG1 may be used as the erase gate of the non-volatile memory NVM1. As shown in FIG. 2, two adjacent memory cells M adjacent to the same gate EG1 may share the gate EG1. As shown in FIG. 2, the top view shape of the gate EG1 may be H-shaped, but the invention is not limited thereto. The material of the gate EG1 is a conductive material such as doped polysilicon.

The gate G1 is located on the substrate 100 on one side of the gate EG1. The gate G1 may be used as the select gate of the non-volatile memory NVM1. The non-volatile memory NVM1 and the pass gate transistor PG1 may share the gate G1. As shown in FIG. 2, in the X direction, two adjacent memory cells M adjacent to the same gate G1 may share the gate G1. As shown in FIG. 2, in the Y direction, the gates G1 in two adjacent memory cells M may be separated from each other. The material of the gate G1 is, for example, a conductive material such as doped polysilicon.

The gate CG1 is located on the substrate 100 between the gate EG1 and the gate G1. The gate CG1 may be used as the control gate of the non-volatile memory NVM1. As shown in FIG. 2, two adjacent memory cells M adjacent to the same gate CG1 may share the gate CG1. As shown in FIG. 2, the top-view shape of the gate CG1 may be a ring shape. The material of the gate CG1 is, for example, a conductive material such as doped polysilicon.

The charge storage layer CS1 is located between the gate CG1 and the substrate 100. As shown in FIG. 2, the charge storage layers CS1 in two adjacent memory cells M may be separated from each other. The charge storage layer CS1 is, for example, a floating gate. The material of the charge storage layer CS1 is, for example, doped polysilicon, undoped polysilicon, or a combination thereof.

Furthermore, the non-volatile memory NVM1 may further include at least one of a dielectric layer 108, a dielectric layer 102, a dielectric layer 110, a dielectric layer 112, a doped region 104, and a doped region 106. The dielectric layer 108 is located between the gate EG1 and the substrate 100. The material of the dielectric layer 108 is, for example, a dielectric material such as silicon oxide. The dielectric layer 102 is located between the gate G1 and the substrate 100. The dielectric layer 110 is located between the gate CG1 and the charge storage layer CS1. The dielectric layer 110 may be a single-layer structure or a multilayer structure. The material of the dielectric layer 110 is, for example, silicon oxide, silicon nitride, or a combination thereof. For example, the dielectric layer 110 may be a composite layer of silicon oxide layer/silicon nitride layer/silicon oxide layer (ONO). The dielectric layer 112 is located between the charge storage layer CS1 and the substrate 100. The material of the dielectric layer 112 is, for example, a dielectric material such as silicon oxide.

The doped region 104 is located in the substrate 100 below the gate EG1. The doped region 104 may extend into the substrate 100 on one side of the gate EG1. The non-volatile memory NVM1 and the pass gate transistor PG1 may share the doped region 104. As shown in FIG. 2, in the X direction, the doped regions 104 in two adjacent memory cells M may be separated from each other. As shown in FIG. 2, in the Y direction, two adjacent memory cells M adjacent to the same doped region 104 may share the doped region 104.

The doped region 106 is located in the substrate 100 on one side of the gate G1. The non-volatile memory NVM1 and the pass gate transistor PG1 may share the doped region 106. As shown in FIG. 2, the doped regions 106 in two adjacent memory cells M may be separated from each other.

Moreover, the SRAM 10 may further include a contact 114. The contact 114 is coupled to the doped region 104. The doped region 104 may be coupled to the bit line BL in FIG. 1 by the contact 114. The material of the contact 114 is, for example, a conductive material such as tungsten. In addition, as shown in FIG. 3, the SRAM 10 may further include a dielectric layer 116 covering the gate EG1, the gate G1, and the gate CG1. As shown in FIG. 3, the contact 114 may be located in the dielectric layer 116. The material of the dielectric layer 116 is, for example, a dielectric material such as silicon oxide.

The gate EG1, the gate G1, the gate CG1, the charge storage layer CS1, and the substrate 100 may be electrically insulated from each other. For example, the gate EG1 and the substrate 100 may be electrically insulated from each other by the dielectric layer 108. The gate G1 and the substrate 100 may be electrically insulated from each other by the dielectric layer 102. The gate CG1 and the charge storage layer CS1 may be electrically insulated from each other by the dielectric layer 110. The charge storage layer CS1 and the substrate 100 may be electrically insulated from each other by the dielectric layer 112. The gate EG1 may be electrically insulated from the gate CG1 and the charge storage layer CS1 by the dielectric layer 116. The gate G1 may be electrically insulated from the gate CG1 and the charge storage layer CS1 by the dielectric layer 116.

Referring to FIG. 1, FIG. 2 and FIG. 4, the pass gate transistor PG2 may include a gate G2, a dielectric layer 118, a doped region 120, and a doped region 122. The gate G2 is located on the substrate 100. The material of the gate G2 is, for example, a conductive material such as doped polysilicon. The dielectric layer 118 is located between the gate G2 and the substrate 100. The material of the dielectric layer 118 is, for example, a dielectric material such as silicon oxide. The doped region 120 and the doped region 122 are respectively located in the substrate 100 on one side and the other side of the gate G2. In some embodiments, the doped region 120 may be used as the source of the pass gate transistor PG2, and the doped region 122 may be used as the drain of the pass gate transistor PG2.

The non-volatile memory NVM2 may be a split gate flash memory. In the present embodiment, the non-volatile memory NVM2 is, for example, a third-generation embedded SuperFlash (ESF3) memory, but the invention is not limited thereto. The non-volatile memory NVM2 may include a gate EG2, a gate G2, a gate CG2, and a charge storage layer CS2.

The gate EG2 is located on the substrate 100. The gate EG2 may be used as the erase gate of the non-volatile memory NVM2. As shown in FIG. 2, two adjacent memory cells M adjacent to the same gate EG2 may share the gate EG2. As shown in FIG. 2, the top view shape of the gate EG2 may be H-shaped, but the invention is not limited thereto. The material of the gate EG2 is a conductive material such as doped polysilicon.

The gate G2 is located on the substrate 100 on one side of the gate EG2. The gate G2 may be used as the select gate of the non-volatile memory NVM2. The non-volatile memory NVM2 and the pass gate transistor PG2 may share the gate G2. As shown in FIG. 2, in the X direction, two adjacent memory cells M adjacent to the same gate G2 may share the gate G2. As shown in FIG. 2, in the Y direction, the gates G2 in two adjacent memory cells M may be separated from each other. The material of the gate G2 is, for example, a conductive material such as doped polysilicon.

The gate CG2 is located on the substrate 100 between the gate EG2 and the gate G2. The gate CG2 may be used as the control gate of the non-volatile memory NVM2. As shown in FIG. 2, two adjacent memory cells M adjacent to the same gate CG2 may share the gate CG2. As shown in FIG. 2, the top-view shape of the gate CG2 may be a ring shape. The material of the gate CG2 is, for example, a conductive material such as doped polysilicon.

The charge storage layer CS2 is located between the gate CG2 and the substrate 100. As shown in FIG. 2, the charge storage layers CS2 in two adjacent memory cells M may be separated from each other. The charge storage layer CS2 is, for example, a floating gate. The material of the charge storage layer CS2 is, for example, doped polysilicon, undoped polysilicon, or a combination thereof.

Furthermore, the non-volatile memory NVM2 may further include at least one of a dielectric layer 124, a dielectric layer 118, a dielectric layer 126, a dielectric layer 128, a doped region 120, and a doped region 122. The dielectric layer 124 is located between the gate EG2 and the substrate 100. The material of the dielectric layer 124 is, for example, a dielectric material such as silicon oxide. The dielectric layer 118 is located between the gate G2 and the substrate 100. The dielectric layer 126 is located between the gate CG2 and the charge storage layer CS2. The dielectric layer 126 may be a single-layer structure or a multilayer structure. The material of the dielectric layer 126 is, for example, silicon oxide, silicon nitride, or a combination thereof. For example, the dielectric layer 126 may be a composite layer of silicon oxide layer/silicon nitride layer/silicon oxide layer (ONO). The dielectric layer 128 is located between the charge storage layer CS2 and the substrate 100. The material of the dielectric layer 128 is, for example, a dielectric material such as silicon oxide.

The doped region 120 is located in the substrate 100 below the gate EG2. The doped region 120 may extend into the substrate 100 on one side of the gate EG2. The non-volatile memory NVM2 and the pass gate transistor PG2 may share the doped region 120. As shown in FIG. 2, in the X direction, the doped regions 120 in two adjacent memory cells M may be separated from each other. As shown in FIG. 2, in the Y direction, two adjacent memory cells M adjacent to the same doped region 120 may share the doped region 120.

The doped region 122 is located in the substrate 100 on the side of the gate G2. The non-volatile memory NVM2 and the pass gate transistor PG2 may share the doped region 122. As shown in FIG. 2, the doped regions 122 in two adjacent memory cells M may be separated from each other.

Moreover, the SRAM 10 may further include a contact 130. The contact 130 is coupled to the doped region 120. The doped region 120 may be coupled to the bit line BLB in FIG. 1 by the contact 130. The material of the contact 130 is, for example, a conductive material such as tungsten. As shown in FIG. 4, the contact 130 may be located in the dielectric layer 116. In addition, as shown in FIG. 4, the dielectric layer 116 may cover the gate EG2, the gate G2, and the gate CG2.

The gate EG2, the gate G2, the gate CG2, the charge storage layer CS2, and the substrate 100 may be electrically insulated from each other. For example, the gate EG2 and the substrate 100 may be electrically insulated from each other by the dielectric layer 124. The gate G2 and the substrate 100 may be electrically insulated from each other by the dielectric layer 118. The gate CG2 and the charge storage layer CS2 may be electrically insulated from each other by the dielectric layer 126. The charge storage layer CS2 and the substrate 100 may be electrically insulated from each other by the dielectric layer 128. The gate EG2 may be electrically insulated from the gate CG2 and the charge storage layer CS2 by the dielectric layer 116. The gate G2 may be electrically insulated from the gate CG2 and the charge storage layer CS2 by the dielectric layer 116.

Referring to FIG. 1 and FIG. 2, the pull-up transistor PU1 may include a gate G3, a doped region 132, a doped region 134, and a dielectric layer (not shown). The doped region 132 and the doped region 134 are disposed in the substrate 100 on two sides of the gate G3. The dielectric layer (not shown) is located between the gate G3 and the substrate 100.

The pull-down transistor PD1 may include a gate G3, a doped region 136, a doped region 106, and a dielectric layer (not shown). The pull-down transistor PD1 and the pull-up transistor PU1 may share the gate G3. The doped region 136 and the doped region 106 are disposed in the substrate 100 on two sides of the gate G3. The pull-down transistor PD1 and the pass gate transistor PG1 may share the doped region 106. The dielectric layer (not shown) is located between the gate G3 and the substrate 100.

The pull-up transistor PU2 may include a gate G4, a doped region 138, a doped region 140, and a dielectric layer (not shown). The doped region 138 and the doped region 140 are disposed in the substrate 100 on two sides of the gate G4. The dielectric layer (not shown) is located between the gate G4 and the substrate 100.

The pull-down transistor PD2 may include a gate G4, a doped region 142, a doped region 122, and a dielectric layer (not shown). The pull-down transistor PD2 and the pull-up transistor PU2 may share the gate G4. The doped region 142 and the doped region 122 are disposed in the substrate 100 on two sides of the gate G4. The pull-down transistor PD2 and the pass gate transistor PG2 may share the doped region 122. The dielectric layer (not shown) is located between the gate G4 and the substrate 100.

Furthermore, the doped region 134 of the pull-up transistor PU1 and the gate G4 of the pull-up transistor PU2 may be coupled to each other by the contact 144. The doped region 140 of the pull-up transistor PU2 and the gate G3 of the pull-up transistor PU1 may be coupled to each other by the contact 146.

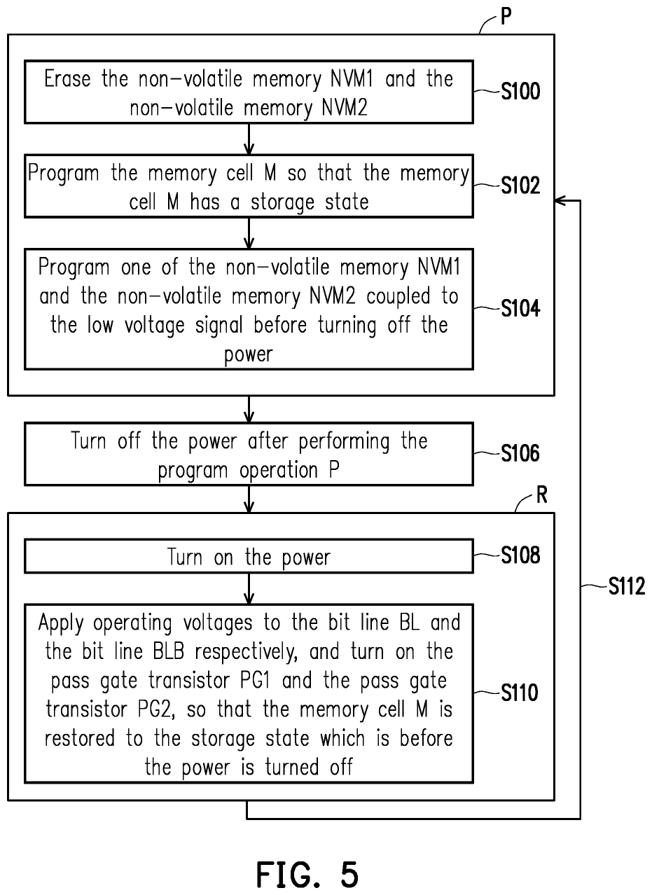

FIG. 5 is a flowchart of operating a SRAM according to an embodiment of the invention.

Referring to FIG. 1 and FIG. 5, the operation method of the SRAM of the present embodiment includes performing a program operation P on the memory cell M. The method of the program operation P includes the following steps. Step S100 is performed to erase the non-volatile memory NVM1 and the non-volatile memory NVM2. Thereby, the non-volatile memory NVM1 and the non-volatile memory NVM2 may have a negative threshold voltage (Vt). The method of erasing the non-volatile memory NVM1 and the non-volatile memory NVM2 is, for example, an FN tunneling method. For example, when erasing the non-volatile memory NVM1 and the non-volatile memory NVM2, the applied voltages are shown in Table 1 below. Hereinafter, Vdd represents the voltage applied to the voltage terminal VDD, Vss represents the voltage applied to the voltage terminal VSS, V_{BL} represents the voltage applied to the bit line BL, V_{BLB} represents the voltage applied to the bit line BLB, V_{WL} represents the voltage applied to the word line WL, V_{EG1} represents the voltage applied to the gate EG1, V_{EG2} represents the voltage applied to the gate EG2, V_{CG1} represents the voltage applied to the gate CG1, and V_{CG2} represents the voltage applied to the gate CG2.

TABLE 1

| | Vdd | V_{SS} | V_{BL} | V_{BLB} | V_{WL} | V_{EG1} | V_{EG2} | V_{CG1} | V_{CG2} |
|---|---|---|---|---|---|---|---|---|---|
| Erase | 1.1 V | ground | 0 V | 0 V | 0 V | 11 V | 11 V | 0 V | 0 V |

Step S102 is performed to program the memory cell M so that the memory cell M has a storage state. In the storage state, one of the inverter INV1 and the inverter INV2 outputs a high voltage signal, and the other of the inverter INV1 and the inverter INV2 outputs a low voltage signal. In the present embodiment, as an example, the inverter INV1 outputs a high voltage signal, and the inverter INV2 outputs a low voltage signal, but the invention is not limited thereto. In other embodiments, in another storage state, the inverter INV1 may output a low voltage signal, and the inverter INV2 may output a high voltage signal. In some embodiments, when programming the memory cell M, a voltage of 0V may be applied to the gate EG1, the gate CG1, the gate EG2, and the gate CG2, so that the non-volatile memory NVM1 and the non-volatile memory NVM2 become the transistors in the turned-on state.

Step S104 is performed to program one of the non-volatile memory NVM1 and the non-volatile memory NVM2 coupled to the low voltage signal before turning off the power. In the present embodiment, as an example, the non-volatile memory NVM2 coupled to the low voltage signal is programmed, but the invention is not limited thereto. The method of programming the non-volatile memory NVM2 coupled to the low voltage signal is, for example, an FN tunneling method. For example, when programming the non-volatile memory NVM2, the applied voltages are shown in Table 2 below. Since the non-volatile memory NVM2 is coupled to the low voltage signal, the volatile memory NVM2 will be programmed after the voltages in Table 2 below are applied. In addition, since the non-volatile memory NVM1 is coupled to the high voltage signal, the volatile memory NVM1 will not be programmed after the voltages in Table 2 below are applied.

TABLE 2

| | Vdd | V_{SS} | V_{BL} | V_{BLB} | V_{WL} | V_{EG1} | V_{EG2} | V_{CG1} | V_{CG2} |
|---|---|---|---|---|---|---|---|---|---|
| Pro- | 1.1 V | ground | 1.1 | 1.1 | 1.1 | 4.5 | 4.5 | 10.5 | 10.5 |
| gram | | | V | V | V | V | V | V | V |

The operation method of the SRAM in the present embodiment may further include the following steps. Step S106 is performed to turn off the power after performing the program operation P.

The operation method of the SRAM in the present embodiment may further include performing a read operation R on the memory cell M. The method of the read operation R may include the following steps. Step S108 is preformed to turn on the power. Step S110 is performed to apply operating voltages to the bit line BL and the bit line BLB respectively, and turn on the pass gate transistor PG1 and the pass gate transistor PG2, so that the memory cell M is restored to the storage state which is before the power is turned off. For example, when the read operation R is performed on the memory cell M, the applied voltages are shown in Table 3 below. In the present embodiment, since the non-volatile memory NVM2 has been programmed and therefore has a high threshold voltage, and the non-volatile memory NVM1 is not programmed and therefore has a negative threshold voltage, after the voltages in Table 3 below are applied, the inverter INV1 can output a high voltage signal, and the inverter INV2 can output a low voltage signal, so that the memory cell M can be restored to the storage state which is before the power is turned off.

TABLE 3

| | Vdd | V_{SS} | V_{BL} | V_{BLB} | V_{WL} | V_{EG1} | V_{EG2} | V_{CG1} | V_{CG2} |
|---|---|---|---|---|---|---|---|---|---|
| Read | 1.1 V | ground | 1.1 V | 1.1 V | 1.1 V | 0 V | 0 V | 1.1 V | 1.1 V |

The operation method of the SRAM in the present embodiment may further include the following step. Step S112 is performed to perform the program operation P on the memory cell M again after performing the read operation R on the memory cell M.

Based on the above embodiments, in the SRAM 10 and the operation method thereof, after the power is turned on again, the memory cell M can be restored to the storage state which is before the power is turned off by the non-volatile memory NVM 1 and the non-volatile memory NVM 2. Therefore, the operation complexity is greatly reduced, and the electrical performance of the memory device is effectively increased.

Although the invention has been described with reference to the above embodiments, it will be apparent to one of ordinary skill in the art that modifications to the described embodiments may be made without departing from the spirit of the invention. Accordingly, the scope of the invention is defined by the attached claims not by the above detailed descriptions.

What is claimed is:

1. A static random access memory, comprising at least one memory cell, wherein the memory cell comprises:
a first inverter and a second inverter, wherein the first inverter and the second inverter are coupled to each other;
a first pass gate transistor coupled between the first inverter and a first bit line;
a second pass gate transistor coupled between the second inverter and a second bit line;
a first non-volatile memory coupled between the first pass gate transistor and the first bit line; and
a second non-volatile memory coupled between the second pass gate transistor and the second bit line.

2. The static random access memory according to claim 1, wherein
the first inverter comprises a first pull-up transistor and a first pull-down transistor coupled to each other, and
the second inverter comprises a second pull-up transistor and a second pull-down transistor coupled to each other.

3. The static random access memory according to claim 1, wherein each of the first non-volatile memory and the second non-volatile memory comprises a split gate flash memory.

4. The static random access memory according to claim 3, wherein each of the first non-volatile memory and the second non-volatile memory comprises:
a first gate located on the substrate;
a second gate located on the substrate on one side of the first gate;
a third gate located on the substrate between the first gate and the second gate; and
a charge storage layer located between the third gate and the substrate.

5. The static random access memory according to claim 4, wherein the first non-volatile memory and the first pass gate transistor share the second gate.

6. The static random access memory according to claim 4, wherein the second non-volatile memory and the second pass gate transistor share the second gate.

7. The static random access memory according to claim 4, wherein two adjacent memory cells share the first gate and the third gate.

8. The static random access memory according to claim 4, wherein a top view shape of the first gate comprises an H shape.

9. The static random access memory according to claim 4, wherein a top view shape of the third gate comprises a ring shape.

10. The static random access memory according to claim 4, wherein the charge storage layer comprises a floating gate.

11. The static random access memory according to claim 4, wherein each of the first non-volatile memory and the second non-volatile memory further comprises:
a first doped region located in the substrate below the first gate; and
a second doped region is located in the substrate on one side of the second gate.

12. The static random access memory according to claim 11, wherein two adjacent memory cells share the first doped region.

13. The static random access memory according to claim 11, wherein the first doped region extends into the substrate on one side of the first gate.

14. The static random access memory according to claim 11, further comprising:
a contact coupled to the first doped region.

15. The static random access memory according to claim 4, wherein the first gate, the second gate, the third gate, the charge storage layer, and the substrate are electrically insulated from each other.

16. An operation method of the static random access memory according to claim 1, comprising performing a program operation on the memory cell, wherein a method of the program operation comprises:
erasing the first non-volatile memory and the second non-volatile memory;
programming the memory cell so that the memory cell has a storage state, wherein in the storage state, one of the first inverter and the second inverter outputs a high voltage signal, and the other of the first inverter and the second inverter outputs a low voltage signal; and
programming one of the first non-volatile memory and the second non-volatile memory coupled to the low voltage signal before turning off power.

17. The operation method of the static random access memory according to claim 16, wherein a method of erasing the first non-volatile memory and the second non-volatile memory comprises a Fowler-Nordheim (FN) tunneling method.

18. The operation method of the static random access memory according to claim 16, a method of programming one of the first non-volatile memory and the second non-volatile memory coupled to the low voltage signal comprises an FN tunneling method.

19. The operation method of the static random access memory according to claim 16, further comprising performing a read operation on the memory cell, wherein a method of the read operation comprises:
turning on the power; and
applying operating voltages to the first bit line and the second bit line respectively, and turning on the first pass gate transistor and the second pass gate transistor, so that the memory cell is restored to the storage state which is before the power is turned off.

20. The operation method of the static random access memory according to claim 19, further comprising:
performing the program operation on the memory cell again after performing the read operation on the memory cell.
